(19) United States
(12) Patent Application Publication
(10) Pub. No.: US 2026/0227440 A1
(43) Pub. Date: Aug. 6, 2026

(54) MODULAR DATA CENTER INSTALLATION, TESTING, MEASUREMENT, AND MAINTENANCE DEVICE

(71) Applicant: VIAVI SOLUTIONS INC., Chandler, AZ (US)

(72) Inventors: Craig Stephen BOLEDOVIC, Walkersville, MD (US); Jerias MITCHELL, Germantown, MD (US); Qui Long JIANG, Gaithersburg, MD (US)

(73) Assignee: VIAVI SOLUTIONS INC., Chandler, AZ (US)

(21) Appl. No.: 19/043,841

(22) Filed: Feb. 3, 2025

(51) Int. Cl. G01R 31/3181; G01R 31/317

(52) U.S. Cl. CPC G01R 31/31813; G01R 31/31713

(57) ABSTRACT

A data center testing device provides field technicians with resources to support multiple aspects of data center testing. The data center testing device includes multiple, integrated and removably connectable modules such as a base module, a user interface module, a testing module, and a battery module. The data center testing device may include a processor, a memory to store machine readable instructions executable by the processor to perform data center testing, an input/output (I/O) device comprising a display, a first connector port assembly comprising a first connection port and a second connection port, and a second connector port assembly comprising a third connection port and a fourth connection port.

### BACKGROUND

Data centers are centralized computer network systems that enable transfer of data and content (e.g., over the internet), and provide storage and backup of the data and content as well. This may include transfer between two data centers a few miles apart, or two data centers connected via trans-oceanic links.

Typically, a data center includes various communications equipment to support network communications. This equipment typically connects to wireline communications networks, which may be comprised of fiber optic cables and coaxial cables.

During operation of a data center, various issues may arise that may require servicing. These issues may include installation, preventative and remedial maintenance, testing and analyzing network communication, and testing network integrity and quality. With proper equipment and training, modern data centers may be serviced by a technician, and thereby reducing a need for an on-site engineer.

### BRIEF DESCRIPTION OF THE DRAWINGS

Features of the present disclosure are illustrated by way of examples shown in the following figures. In the following figures, like numerals indicate like elements, in which:

FIG. 1A illustrates a perspective view of a data center testing device including a base module and an input/output (I/O) device, according to an example of the present disclosure;

FIG. 1B illustrates a back side view of a base module, according to an example of the present disclosure;

FIG. 1C illustrates a top view of a base module, according to an example of the present disclosure;

FIG. 1D illustrates a bottom view of a base module, according to an example of the present disclosure;

FIG. 1E illustrates an exploded perspective view of a data center testing device including an I/O device, a base module, and dual expansion modules, according to an example of the present disclosure;

FIG. 1F illustrates an exploded perspective view of a data center testing device including a removably connected module, according to an example of the present disclosure;

FIG. 2 illustrates a test process automation workflow, according to an example of the present disclosure;

FIG. 3A illustrates a high level system diagram of test process automation, according to an example of the present disclosure;

FIG. 3B illustrates a graphical uer interface (GUI) for a data center testing device having an automated test plan, according to an example of the present disclosure;

FIG. 4A illustrates a system diagram of a data center testing device connected to a workstation by an Ethernet connection for remote access and control, according to an example of the present disclosure;

FIG. 4B illustrates a system diagram of a data center testing device connected to a workstation by a wireless network connection for remote access and control, according to an example of the present disclosure;

FIGS. 5A-5E illustrate various aspects of a printed circuit board (PCB) that is included in a data center testing device, according to an example of the present disclosure;

FIG. 6 illustrates a back side view of multiport testing module, according to an example of the present disclosure;

FIG. 7A illustrates a diagram of data center testing device connected to workstation, according to an example of the present disclosure;

FIG. 7B illustrates a diagram of data center testing device coupled to a cable to be tested, according to an example of the present disclosure;

FIG. 8 illustrates a method for testing a cable for a data center, according to an example of the present disclosure; and

FIG. 9 illustrates a method for testing a cable for a data center, according to an example of the present disclosure.

### DETAILED DESCRIPTION

For simplicity and illustrative purposes, the present disclosure is described by referring mainly to examples thereof. In the following description, details are set forth in order to provide an understanding of the present disclosure. It will be readily apparent however, that the present disclosure may be practiced without limitation to these details. In other instances, some methods and structures have not been described in detail so as not to unnecessarily obscure the present disclosure.

Throughout the present disclosure, the terms “a” and “an” are intended to de at least one of a particular element. As used herein, the term “includes” means includes but not limited to, the term “including” means including but not limited to. The term “based on” means based at least in part on.

Data centers enable sharing of data and content and provide storage and backup for redundancy, and typically house compute and storage resources for applications, data, and content. A data center typically includes various electronic equipment to support network communication(s).

The electronic equipment of a data center generally connects to wireline networks, which may be comprised of fiber optic cables and coaxial cables. The sharing may take place between two data centers a few miles apart, or two data centers connected via trans-oceanic lines.

One technology that may be utilized to enable sharing across data centers is Data Center Interconnection (DCI) technology. DCI may be utilized to implement high-speed data packet transfer for two or more data centers over various distances.

It may be appreciated that data center operations may depend on a wide range of design and logistical variables. Examples of these variables may include, among others, a location of the data center(s), distance between data centers, bandwidth, cost, and capacities of local service providers.

In some instances, a bandwidth of a data center may be expressed as a data rate. Typical data rates may range from, for example, ten (10) gigabits per second (also referred to as “10 G”) to eight-hundred (800) gigabits per second (also referred as “800 G”). Presently, many data centers are migrating from implementation of 400 G (i.e., four-hundred (400) gigabits per second) data rates to implementation of 800 G data rates, particularly for communication “inks” extending from a first data center to a second data center.

Another variable in data center configuration may be cable types that may be used to connect various network devices. These cables are typically pre-assembled with predetermined form factors, and typically enable “plug and play” implementation. Moreover, these cables may be accommodate various data rates, may be “active” or “passive,” and may be “split” (i.e., a 400 G cable may be split into two 200 G cables).

A first example of a cable type may be a direct attach copper (DAC) cable. DAC cables are copper cables with transmission modules (i.e., connectors) that enable the DAC cable to connect directly into a port of a network device (e.g., a switch, router, server, or data storage device). A second example of a cable type may be active optical cable (AOC). AOC cables are a fiber optic cables that typically employ electrical-to-optical conversion to connect to standard electrical interfaces.

Yet another variable in data center configuration is the connector type used to connect a network cable to a network device. Typically, a module of the connector is connected to a device, where the connector is placed inside of a housing element (or “cage”), which guides the module into a connector element of the device. For example, in some instances, certain data center devices may utilize an Octal Small Form Factor Pluggable (OSFP) connector. An OSFP connector may, for example, typically accommodate up to a 400 G data rate. In other instances the data center devices may utilize an Octal Small Form Factor Pluggable (QSFP) connector. The QSFP connector may, for example, often accommodate up to a 800 G data rate (e.g., QSFP-DD, QSFP+, etc.).

With all these variables at play, it may be appreciated that testing of data center operations, including devices and configurations, may come with a number of significant complexities. These complexities may relate to device installation and optimization, preventative and remedial maintenance, integration of network hardware and interconnect elements, maintaining and repairing data center equipment, testing and analyzing network communication, and testing network integrity and quality. For example, data center testing may be directed to testing aspects of connections between data centers (i.e., “link testing”), or may be directed to testing aspects of connection between data center testing devices (e.g., cable testing). Furthermore, testing may be required prior to installation or during operation. In addition, data center testing may include a myriad of particular tests, such as bit-error rate (BER) testing, forward error correction (FEC) testing, etc.

In some instances, a typical testing scenario may often require use of two data center testing devices. Specifically, in some instances, a data center testing device (e.g., a handheld device) may include only one port having one connector type (e.g., either QSFP or OSFP connector). For example, this may not enable testing associated with two different connector types, or otherwise may require use of an adapter. In such instances where two data center devices may be required, a first data center testing device may be implemented to run a test script, while the second tester is typically employed to monitor through and received (i.e., “loopback”) communications.

In some instances, these complexities may require the expertise of one or more on-site engineers. However, this may significantly increase operational costs of a data center. With proper equipment and training, data centers may instead be serviced by a technician, and thereby reducing a need for an on-site engineer. With proper equipment, a technician may be able to troubleshoot and optimize a large number of the issues that may arise during data center operations.

A data center installation, testing, measurement, and maintenance device, referred to herein as a data center testing device or testing device, provides a configurable, multi-protocol testing system for telecommunication systems. For example, the data center testing device described herein provides field technicians with resources to support multiple aspects of data center testing, including testing for installation and maintenance of data centers, and testing related to, and not limited to, network devices, fiber optic cables and optical signals, coaxial cables and antennas.

The data center testing device as described provides multiple technical advantages over existing devices. The data center testing device delivers improved efficiencies as it may replace multiple independent devices that may typically be required for testing scenarios, and provide additional measurements and insights that can improve installation and maintenance of data centers.

As described in further detail below, the data center testing device is modular, in that different modules may be added to the data center testing device to facilitate different types of testing. A module may be, among other things, a software or hardware element, or a combination of hardware and software elements that may be utilized in conjunction with the data center testing device (as further described below). Thus, the data center testing device is scalable, because modules can be added to the data center testing device to accommodate new testing requirements and scenarios. In addition, the data center testing device may be mounted on a variety of data center devices, such as a server rack (i.e., it may be “rack-mountable”).

Also, as described in further detail below, the data center testing device may include job manager software that enables automated testing to be performed. A job may comprise one or more tests to be performed by the data center testing device in a specified sequence. One or more jobs may be created and stored in the data center testing device for different tasks. Jobs, including workflows for testing, can be defined centrally and downloaded to data center testing devices at multiple data centers, eliminating the variability of manual procedures and thereby driving consistent, repeatable results, regardless of technician skill or experience level.

The data center testing device permits data center technicians to test, among other things, fiber, radio frequency (RF), Spectrum Analysis (SA), Common Public Radio Interface (CPRI), and Ethernet from a single instrument, replacing multiple independent devices. Examples of other tests the data center testing device may perform include system development, Ethernet traffic load, transponder hardware validation, BER testing, FEC compliance and validation, and interconnect (IC) development and validation. In an example, and as will be described in further detail below, the data center testing device includes modules that provide the ability to test specific protocols all in one device.

By implementing use of a data center testing device as described, training for technicians shifts to learning of the test process itself, which is faster and easier to learn, rather than on analysis of technical information, which is generally time-consuming and overwhelming for new technicians. Furthermore, the job manager software can eliminate wasted technician time regarding trying to remember which tests to run and how to run them. The above-described technical advantages and other technical advantages are further described below.

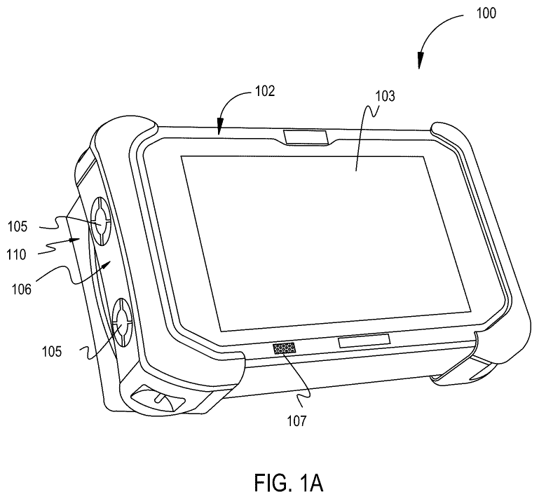

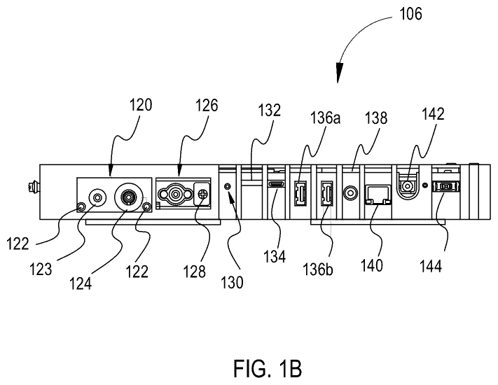

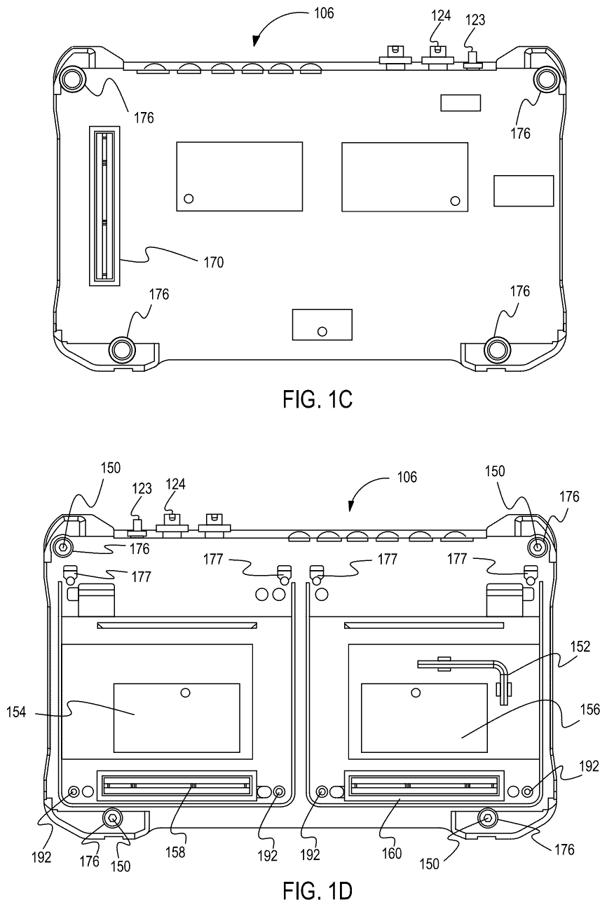

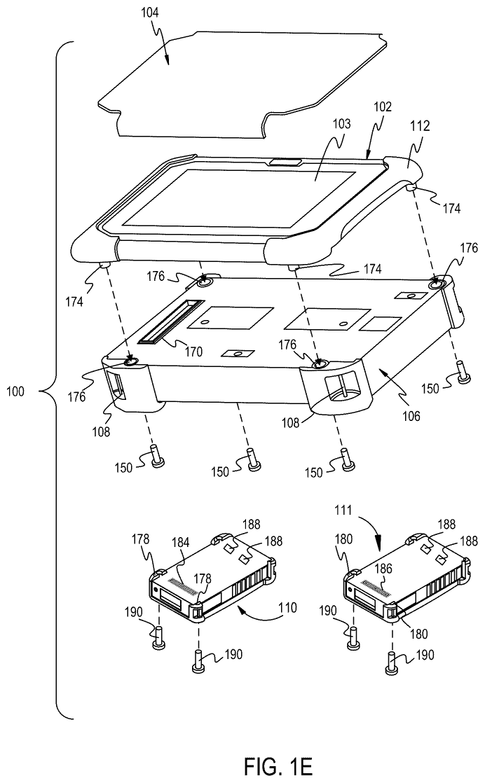

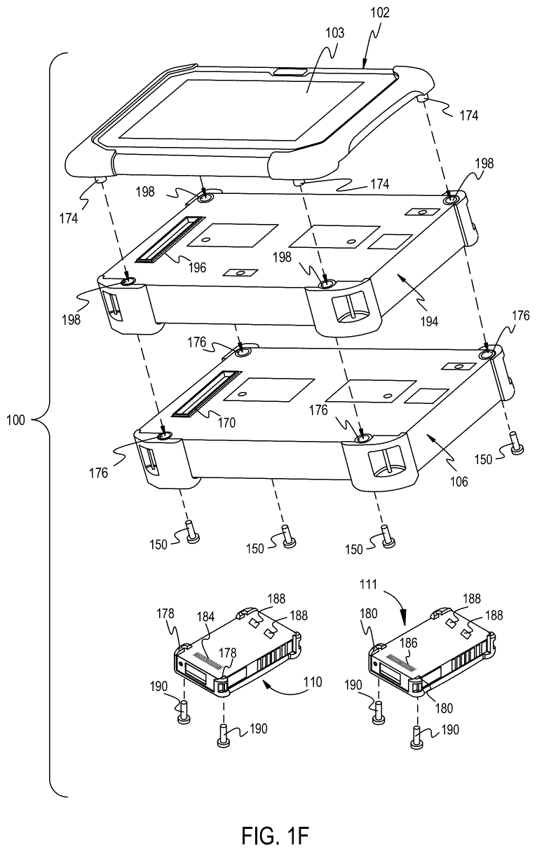

FIG. 1A illustrates a perspective view of a modular data center testing device 100 including base module 106 and I/O device 102 (which may be removably connected), according to an example of the present disclosure. Data center testing device 100 may be a modular hand-held device comprising removably connectable field replaceable modules for data center installation, testing, measurement, and maintenance. According to an example, data center testing device 100 includes removably connectable I/O device 102, and a removably connectable base module 106.

According to an example, I/O device 102 includes a display 103 that provides user control and information. According to an example, the display 103 may be a touch screen, e.g., liquid crystal display (LCD) touchscreen. The data center testing device 100 provides user information including: a listing of jobs, a listing of reports to be compiled, a compilation of executed test results in a test report or test reports, and an interface control with a work station or server. Base module 106 provides hardware, software and firmware to control data center testing device 100.

According to the illustrated example of FIG. 1A, ventilation ports 105 are provided to the outer structure of base module 106 to facilitate internal cooling of components by way of an internal cooling unit. Loudspeaker 107 provides audio information. Base module 106 provides a structural base for data center testing device 100.

According to an example, data center testing device 100 may be configured in a variety of assemblies with a plurality of different removably connectable modules to support workflow and project specifications. According to the illustrated example of FIG. 1A, data center testing device 100 includes first expansion module 110 removably connected to the bottom of base module 106.

FIG. 1B illustrates a back side view of base module 106, according to an example. Base module 106, similar to other modules described herein, includes a plurality of modular elements used for data center installation, testing, measurement, and maintenance.

According to an example, base module 106 includes PM-DL module 120, also known as a power meter/datalink optical module. PM-DL module 120 and other modules described herein may be factory installed with base module 106 or one or more modules may be attached to base module 106 by a user. In an example, PM-DL module 120 is secured by way of connection members 122. PM-DL module 120 includes power meter port 123 and TS-PC port 124, also known as a Talkset-Datalink port. Power meter port 123 is used to determine optical power of a fiber under test. TS-PC port 124 is used to communicate voice or data with another device along an optical fiber.

According to an example, base module 106 also includes VFL module 126, also known as a Visual Fault Locator (VFL) module, to provide detection of a visual fault location. A VFL test uses brightly visible light to check patch cords for defects and verify continuity.

According to an example, base module 106 includes a number of additional inputs and control interfaces as follows. Reset button 130 provides a hard reset of data center testing device 100. Reset button 130 may be depressed with a small object, such as an extended paperclip. Micro-SD port 132 provides removable storage to data center testing device 100 by accepting a micro-SD card. The micro-SD card may provide memory for storing data center data, predetermined setup configurations, test results, and compiled reports. USB-C port 134 provides an interface to data center testing device 100 according to the USB-C standard. USB-C port 134 also provides a debug-serial-port to support testing and trouble-shooting of data center testing device 100. An audio interface, and/or headset may be multiplexed with USB-C port 134 by way of an external adapter, such as a USB-C or 3 mm adapter. A pair of USB-A Interfaces 136a and 136b provides support for connection of USB 2.0/3.0 peripherals, such as an external fiber microscope, set forth in greater detail below.

Audio jack 138 provides a direct audio interface by accepting a 3 mm male plug. Ethernet port 140 is RJ-45 jack to provide 10/100/1000-BaseT Ethernet management. On/Off switch 142 is configured to turn data center testing device 100 on and off. DC-input 144 is configured to receive DC power for data center testing device 100 from an external power supply. Although not illustrated in FIG. 1B, a mini USB port may also be provided. Base module 106 may also include a wireless network module to support wireless network communication and a Bluetooth module to support Bluetooth communication with an external device, such as a Bluetooth audio headset.

FIG. 1C illustrates a top view of base module 106, according to an example of the present disclosure. Base module 106 includes a plurality of through holes 176 to mate with corresponding protrusions 174 in the housing of I/O device 102. Base module 106 provides electrical power and communication to I/O device 102 or other modules, including solution modules and expansion modules, by way of base module backplane interface 170.

FIG. 1D illustrates a bottom view of base module 106, according to an example of the present disclosure. Base module 106 includes a plurality of through holes 176 to receive a plurality of connection members 150 to removably secure base module 106 to I/O device 102. According to an example, connection device 152 is disposed within base module 106 to support field replacement of different removably connectable modules (attachable to a top side of base module 106). Base module 106 includes a plurality of access panels, such as access panels 154 and 156 to support factory installation of various internal modules, such as the wireless network module or Bluetooth module.

Base module 106 includes first expansion interface 158 and second expansion interface 160 to provide electrical communication and power to a plurality of different expansion modules. According to an example, the bottom of base module 106 includes recesses to receive corresponding cleats from expansion modules, such as cleats 188 shown in FIG. 1E of expansion modules 110 and 111. Threaded bushings 192 then receive structural members, which pass through holes in the expansion modules to be received therein.

FIG. 1E illustrates an exploded perspective view of data center testing device 100 including I/O device 102, base module 106, and expansion modules 110 and 111, according to an example of the present disclosure. An optional screen cover 104 may be removably attached to the housing of I/O device 102 to provide protection to display 103. Base module 106 is removably connected to I/O device 102 by a plurality of connection members 150. According to an example, I/O device 102 includes a plurality of protrusions 174 that are configured to be received within through-holes 176 defined by the structural housing of base module 106. According to an example, first expansion module 110 has structure defining holes 178 and expansion module 111 has structure defining holes 180. Connection members 190 pass through holes 178 and 180 and are received within threaded bushings 192 of base module 106. Cleats 188 of expansion modules 110 and 111 are received within recesses 177 in the bottom of base module 106. First expansion module 110 includes expansion interface 184 to communicate power and control signals with base module 106. Likewise, expansion module 111 includes expansion interface 186 to communicate power and control signals.

FIG. 1F illustrates an exploded perspective view of data center testing device 100 including a removably connected module 194, according to an example of the present disclosure. Upon integration of first solution module 194, base module 106 provides electrical power and communication to first solution module 194 by base module backplane interface 170. Likewise, first solution module 194 provides electrical power and communication to I/O device 102 by way of top solution interface 196. First solution module 194 also includes a bottom solution interface (not shown) connectable to base module backplane interface 170, described in greater detail below. According to another example, a second solution module may be optionally disposed between first solution module 194 and base module 106. The base module backplane interface 170 connects power and communication (e.g., carrying data) busses of the base module 106 to modules connected to the base module 106 via base module backplane interface 170 or other interfaces.

First solution module 194 has a similar housing and form factor to base module 106 to provide integration between I/O device 102 and base module 106. First solution module 194 includes a plurality of through holes 198 to mate with corresponding protrusions 174 in the housing of I/O device 102. First solution module 194 provides electrical power and communication to I/O device 102 by way of top solution interface 196. First solution module 194 is removably connected to I/O device 102 by connection members 150.

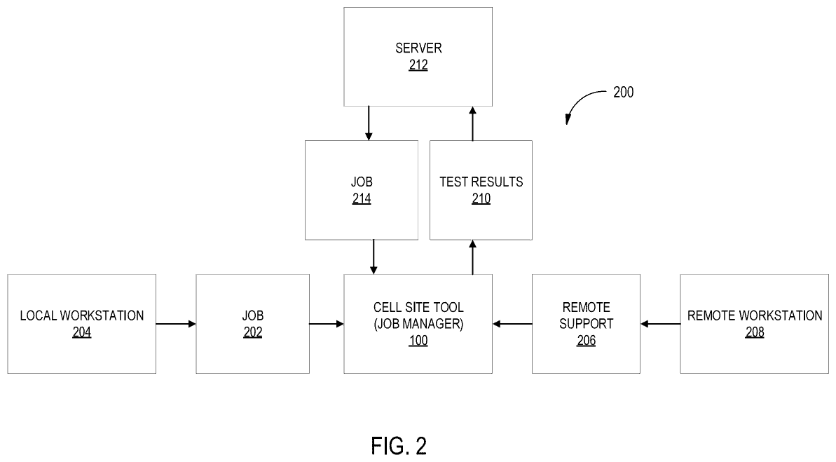

FIG. 2 illustrates test process automation workflow 200, according to an example of the present disclosure. A workstation, such as local workstation 204, creates a job, such as job 202, which may be loaded onto data center testing device 100. Alternatively, server 212 may load a job, such as job 214, onto data center testing device 100. Data center testing device 100 may receive remote support 206 from remote workstation 208.

Data center testing device 100 may deliver test results 210 to server 212. According to an example, data center testing device 100 may also deliver test results to local workstation 204 or remote workstation 208. Data center testing device 100 includes job manager software, known simply as job manager, which presents GUIs to manage jobs and execute tests. A job may include, among other things, a set of tests to be executed by data center testing device 100. The job manager can be used to define and customize jobs, and coordinates tasks and results across multiple testing devices and modules connected to data center testing device 100. The job manager displays step-by-step instructions to a user for executing tests with data center testing device 100. Job manager also displays progress and test results related to tests executed by data center testing device 100.

Data center testing device 100 supports communication with centralized management (CM) software running on server 212, which is presented to a user as a graphical user interface (GUI). The CM software organizes and pushes test configurations and job assignments 214 to data center testing device 100. The CM software automatically collects and organizes tests results 210 executed by data center testing device 100. The CM software presents a GUI on server 212, including a server dashboard of Key Performance Indicators (KPIs).

Data center testing device 100 may receive remote support 206, including communication and control, by remote workstation 208. Remote workstation 208 provides remote access and control of data center testing device 100, and also supports file transfer.

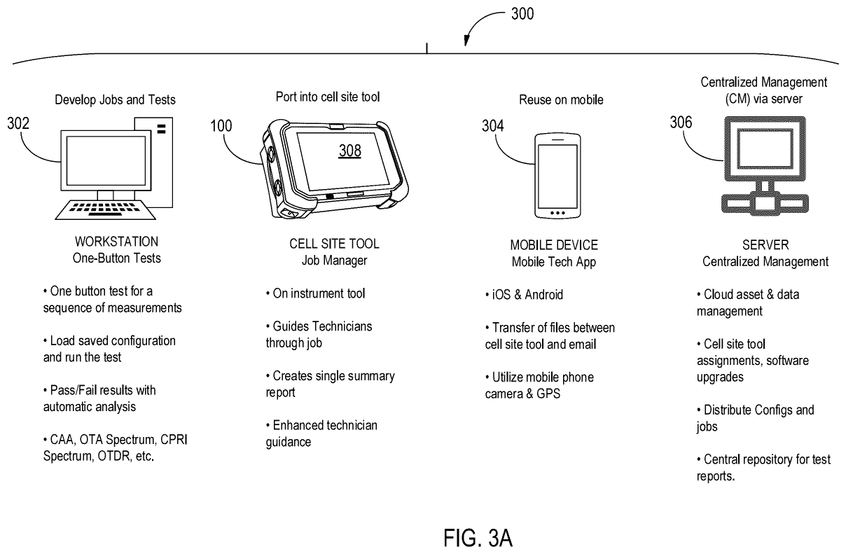

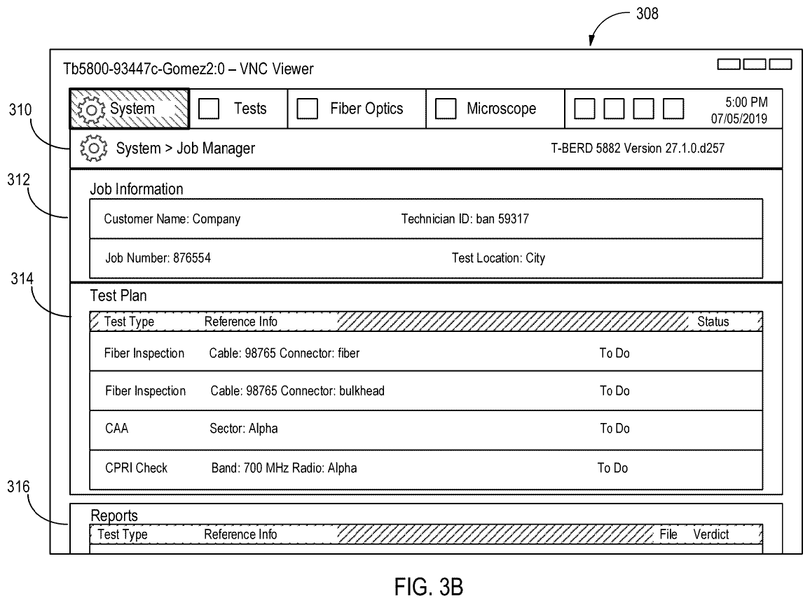

FIG. 3A illustrates a high level system diagram of test process automation 300, according to an example of the present disclosure. Test process automation 300 includes cooperation and communication between data center testing device 100, workstation 302, mobile device 304, and server 306. Workstation 302 is used to develop jobs, tests, and one-button tests. A one button test may be developed to execute a sequence of measurements by data center testing device 100. Workstation 302 may communicate with data center testing device 100 to load a saved configuration into data center testing device 100, and optionally control the data center testing device to run the test. Workstation 302 may develop a test with Pass/Fail results, and configure data center testing device 100 to perform automatic analysis. According to an example, workstation 302 may develop automated tests for CAA, OtA Spectrum, CPRI Spectrum, OTDR, etc.

Data center testing device 100 runs a job manager application, which may control the data center testing device 100 to perform the tests. The job manager application may guide technicians through a job, and create a single summary report corresponding to the executed job tests. According to an example, the job manager application also includes enhanced technician guidance, which may be selected by the technician to display step-by-step instructions on GUI 308 of data center testing device 100.

Mobile device 304 is a smart phone running an iOS or Android operating system and a mobile tech application. By using the mobile tech application on mobile device 304, a technician may communicate with server 306 and data center testing device 100 to transfer files such as a summary report corresponding to executed job tests. The mobile tech application may also be used to transfer files between data center testing device 100 and email. Mobile device 304 is a smart phone that includes a camera and GPS. A technician may control mobile device 304 to transfer GPS information and photographs to data center testing device 100 corresponding to a test. The job manager application on data center testing device 100 associates the GPS information and the photographs with a test, and stores the information in a corresponding summary report.

Server 306 runs centralized management software (CM) to provide centralized management of jobs executed by data center testing device 100, and other similarly configured data center testing devices. A service provider may manage thousands of similarly configured data centers and seek to ensure that all technicians servicing the data centers perform the same tests. According to an example, a service provider may deliver the same jobs, tests, and one button tests to data center testing devices in their fleet. According to an example, server 306 provides asset and data management, and delivers data center testing device assignments and software upgrades. Server 306 may distribute configurations and jobs to data center testing device 100, and serve as a central repository for test reports.

FIG. 3B illustrates a graphical user interface (GUI) 308 for data center testing device 100 having an automated test plan, according to an example of the present disclosure. Data center testing device 100 runs a job manager application, which is presented to a technician by job manager indication 310. According to an example, GUI 308 presents job manager 312, including customer name, job number, technician ID, and test location. According to an example, GUI 308 presents test plan 314, also known as a Job, indicating tests to be executed by data center testing device 100, and test status. According to the illustrated example, test plan 314 includes a fiber inspection test on cable 98765 for the fiber, a fiber inspection test on cable 98765 for the bulkhead, a CAA test at sector alpha, and a CPRI test at 700 MHz for radio alpha. According to an example, GUI 308 presents reports 316 of tests that have been previously executed by data center testing device 100 for review and comment by a technician. For example, a technician may add GPS and photographs to a test indicated in Reports 316.

According to an example, a technician is able to determine certain parameters and configurations of the data center testing device. According to an alternate example, certain parameters and configurations of the data center testing device may be predetermined.

A data center testing device may provide an option to initialize configurations with the last saved settings and the option to initialize configurations from a saved user profile. A data center testing device may provide an option to initialize configurations to factory defaults.

A data center testing device may also provide the ability to generate a report that records the configurations used for an automated test instance and includes the results analysis with the option to include pass/fail determinations and screenshots. A data center testing device may also provide the ability to navigate through the steps of configuring the test as well as view the test results in an intuitive user experience. A data center testing device may also provide a progress bar/overall test status widget that is always visible to give the user an indication of how the test is proceeding in time. A data center testing device may also provide a task selection screen from which a technician may invoke the automated test and have the ability to see a snapshot of the status of tasks scheduled to run as well as a means of navigating quickly to each task result screen.

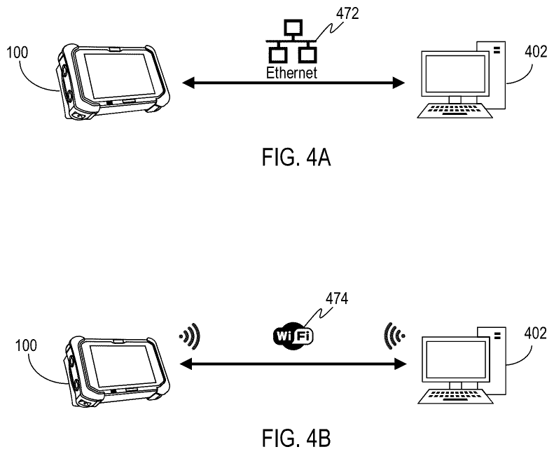

FIG. 4A illustrates a system diagram of data center testing device 100 connected to workstation 402 by an Ethernet connection 472 for remote access and control, according to an example of the present disclosure. Remote access allows permits viewing and control of I/O device 102 of data center testing device 100 from a remote location using workstation 402. In addition to configuring data center testing device 100 and performing tests, remote access permits file transfer to and from data center testing device 100 using the device's file manager utility. A technician with remote access can rename and delete files, or create, rename, and delete directories. A remote access utility is downloaded and extracted onto workstation 402. Remote access may be established using a wired Ethernet connection 472.

According to an example, a remote access utility may also be launched on data center testing device 100 by interacting with a GUI via I/O device 102. The remote access connection is then automatically initiated. After a connection is established to the server, the device displays a message with a required code to access to the device remotely. To access device 100 from workstation 402, the code is input into the workstation utility to access device 100.

To test the connection between workstation 402 and data center testing device 100 the steps are: on workstation 402, launch the remote access utility. In the workstation utility, a test connection button is selected, and a connection test automatically launches. To display connection log details in real time, a full logs button is selected on the workstation. The connection log then appears, and provides the following information: upload and download speed from device to server; and latency between device and server. After analyzing the results, from the workstation: select a clear test results button to delete the current table, and retest the connection if desired. If the connection is deemed to be valid, the access code is then entered and a remote access connection is established.

FIG. 4B illustrates a system diagram of data center testing device 100 connected to workstation 402 by a wireless network (e.g., WiFi) connection 474 for remote access and control, according to an example of the present disclosure. According to the example, remote access may be established using wireless network connection 474 by enabling a wireless network module internal to base module 106.

As discussed above, it is desirable to have a data center testing device that provides multiple ports that are able to accommodate multiple connection types. For example, the data center testing may be able to accommodate both QSFP (e.g., QSFP-DD 800) and OSFP (e.g., OSFP-800) connection types, up to 800 G data rates. In some examples, a data center testing device as described herein may provide testing capabilities for various cable types (e.g., DAC, AOC etc.), for various data rates (e.g., up to 800 G), and may support multiple connector types.

In some examples, the data center testing device may provide two (dual) user-selectable QSFP-DD800 ports and two (dual) OSFP-800 ports, wherein connecting one end of a cable in a first port and connecting (or “looping”) a second end of the cable to a second port may enable testing of QSFP cables, OSFP cables, and (mixed) QSFP to OSFP cables (and vice versa). Accordingly, as will be discussed further below, the data center testing device may provide testing interchangeability, in that it may accommodate testing solutions in a variety of linking and cabling configurations. Furthermore, the data center device may also enable backup testing options in case of failure of one of the multiple ports. As a result, instead of requiring two testing devices, the data center testing device as described herein may enable various testing solutions without a need for a second testing device. Furthermore, these features may be made available on a data center testing device that may be handheld, and therefore may provide significant advantages and be of significant convenience to an on-site technician.

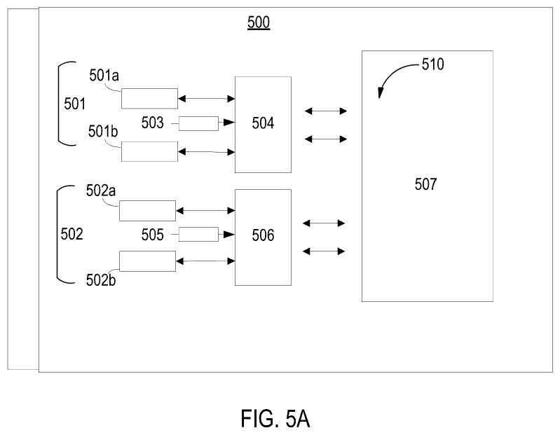

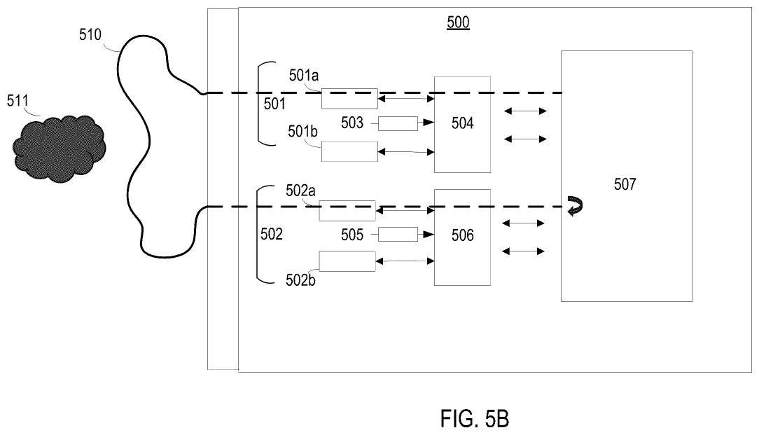

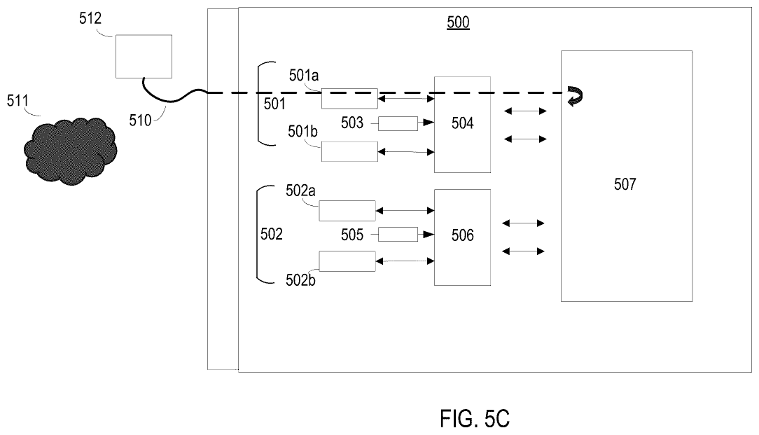

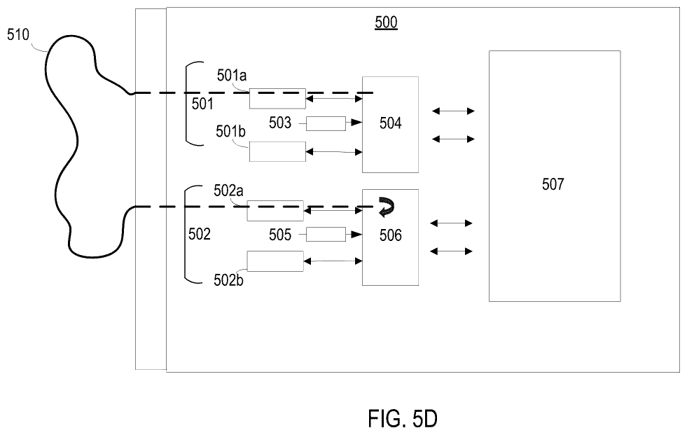

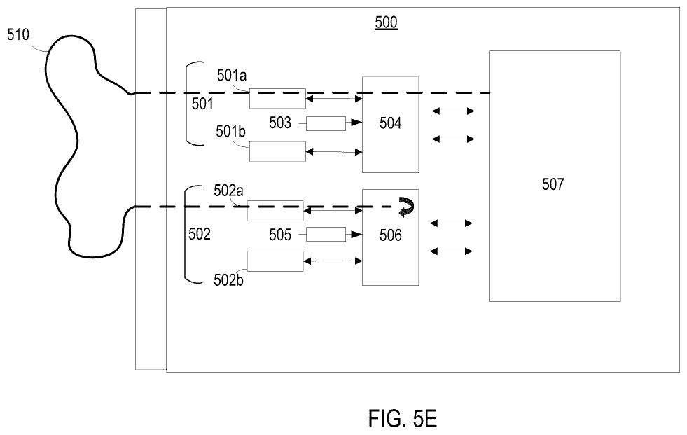

FIGS. 5A-5E illustrates various aspects of a printed circuit board (PCB) 500 that may be included in a data center testing device, according to an example of the present disclosure. In some examples, the PCB 500 in FIGS. 5A-5E may include connection ports for multiple connection types (e.g., QSFP-DD800, OSFP-800, etc.), and may enable both ends of a cable (e.g., AOC, DAC, etc.), having either connection type, to be plugged into the data center testing device. In some examples, and as described further below, this may enable testing of the DAC and AOC cables via a single testing device.

In some examples, the PCB 500 may be included in a pluggable module, such as a testing module, to be plugged into a data center testing device as described. In particular, in some examples, the pluggable module may be similar to other modules described herein, and in some examples, may be plugged on to a side portion of a data center testing device (e.g., the data center testing device 100), such as where the base module 106 may be shown in FIG. 1A.

In some examples, the PCB 500 may include connection ports for QSFP and OSFP connection types, thereby enabling both ends of a cable having either a QSFP connection type or OSFP connection type to be plugged into a data center testing device. These connection ports may enable testing at various data rates (e.g., 400 G, 800 G, etc.).

More specifically, in some examples, a data center testing device having a module incorporating the PCB 500 may provide multiple, user-selectable QSFP-DD800 ports and multiple, user-selectable OSFP-800 ports. In some examples, connecting one end of a cable in a first port and connecting (or “looping”) a second end of the cable to a second port may enable testing of QSFP-DD800 cables, OSFP800 cables, and (mixed) QSFP-DD800 to OSFP-800 cables (and vice versa).

In the example illustrated in FIG. 5A, the PCB 500 may include a first connection port assembly 501 and a second connection port assembly 502. The first connection port assembly 501 may include a first QSFP port 501a (e.g., a QSFP-DD800 connector type) and a first OSFP port 501b (e.g., an OSFP-800 connector type).

In some examples, the first connection port assembly 501 may be coupled to a low-voltage differential signaling (LVDS) oscillator 503, which may further be coupled to multiplexer element (MUX) 504 and a field-programmable gate array (FPGA) 507. The first connection port assembly 501, the MUX 504, and the FPGA 507, may be capable of supporting testing for up to 800 G data rates.

As discussed in further detail below, the first connection port assembly 501 may be utilized as a primary test source for cable testing (e.g., AOC cables, DAC cables, etc.). The first connection port assembly 501, the MUX 504, and the FPGA 507 may generate and/or propagate data traffic that may be utilized during, for example, BER or FEC testing.

In addition, the first connection port assembly 501, the MUX 504, and the FPGA 507 may enable an array of switch testing as well. In conjunction with the Open Systems Interconnection (OSI) model, these elements of the PCB 500 may facilitate testing of Layer 2 (L2) and Layer 3 (L3). In some examples, L2/L3 switch testing may involve testing an ability of the switch to direct traffic from a particular ingress port to a (correct) egress port, and switching traffic according to specific key performance indicators (KPIs). In particular, in some instances, the KPIs may be measured under different traffic conditions that include several flows with different flow traffic characteristics. Examples of these KPIs may include, but are not limited to, throughput, delay, delay variation, traffic type (e.g., constant, ramp, burst, etc.). Furthermore, in some instances, it may be desirable to measure a service disruption time of the switch by manually emulating a service disruption, and measuring the time for the device-under-test (DUT) to switch from a working line to a protection line.

Also, the first connection port assembly 501, in association with the MUX 504 and the FPGA 507, may facilitate DCI link testing. In some examples, DCI testing may include, but is not limited to, testing of basic connectivity, throughput, delay, and delay variations. Additional DCI testing may include testing of optical transceivers and/or interconnect cables used in the DCI equipment that connect a plurality of data centers. In particular, some transceivers used in DCI applications (e.g., implemented via ZR/ZR+ transceivers) perform digital signal processing functions that may consume significantly higher power than traditional transceivers. In some instances, the higher power consumption may imply that the test equipment may be able to provide sufficient power and cooling.

Similar to the first connection port assembly 501, the second connection port assembly 502 may include a second QSFP port 502a (e.g., a QSFP-DD800 connector type) and a second OSFP port 502b (e.g., an OSFP-800 connector type). The second connection port assembly 502 may be coupled to a LVDS oscillator 505, which may further be coupled to MUX 506 and FPGA 507. In some examples, the second connection port assembly 502 may be capable of supporting up to 400 G data rates, and may enable testing of both OSFP 800 and QSFP-DD 800 connection types.

In some examples, by providing the first connection port assembly 501 and a second connection port assembly 502, both having dual QSFP, OSFP ports, the PCB 500 may enable a “loopback” tests that may accommodate one or more connection types. So, for example, during testing, a first end of a cable 510 (e.g., an AOC cable having QSFP-DD800 connectors on both ends) may be plugged in to a port of the first connection port assembly 501 and a second end of the cable 510 may be plugged into a port of the second connection port assembly 502. It may be appreciated that although the examples herein may focus primarily on the OSFP800 and QSFP-DD800 connector types, any other type of connector types may be implemented instead or in addition to.

Typically, while conducting a BER test, the FPGA 507 may generate data (also referred to as “traffic”). This data may have a particular scheme, or “pattern” (e.g., a pseudo random binary sequence (PRBS)). Also, when conducting a FEC test, etc., the FPGA 507 may generate the traffic and provide encoding, analysis, and error correction as well.

The traffic may be sent through the MUX 504, and sent out of the port of the first connection port assembly 501. The traffic may then be sent over the cable 510, received by the port of the second connection port assembly 502, and then received at the MUX 506. The traffic may then be sent back (“looped back”) through the port of the second connection port assembly 502 over the cable 510 to the port of the first connection port assembly 501 for analysis to the determine if the cable is functional. This may be referred to as a “deep” loopback test.

As discussed above, the first connection port assembly 501 may be able to support deep loopback testing at up to 800 G data rates, while the second connection port assembly 502 may be able to support deep loopback testing at up to 400 G data rates. As a result, according to some examples, the deep loopback path, available at 400 G data rates and below, is illustrated in FIG. 5B. In other examples, as discussed above, the deep loopback test may be utilized to implement a network traffic test of a network 511 at 400 G data rates as well.

In order to conduct a deep loopback test at 800 G data rates, a second data center testing device 512 may be coupled to the FPGA 507 of the first data center testing device via the first connection port assembly 501, as illustrated in FIG. 5C. In some examples, the cable 510 may be coupled to the second data center testing device 512 to test the cable 510, while in other examples, the cable 510 may be coupled to the network 511 to conduct a network traffic test at 800 G data rates as well.

The PCB 500 may also be configured to enable a “shallow” loopback test as well. In these examples, the traffic may not go all the way to the FPGA 507, but instead is sent to and returned by the MUX 506. Specifically, the traffic may be generated by the MUX 504, sent through the first connection port assembly 501, over the cable 510 and to the second connection port assembly 502 and the MUX 506. The traffic may then be returned from the MUX 506 over the cable 510 to the MUX 504 via the first connection port assembly 501 for analysis to the determine if the cable is functional. In some examples, because the shallow loopback testing does not involve the FPGA 507, both the first connection port assembly 501 and the second connection port assembly 502 may be able to support shallow loopback testing at up to 800 G data rates. A shallow loopback path implemented to test a cable is illustrated in FIG. 5D.

In some examples, the second connection port assembly 501 may receive and pass through (“loop”) data at an 800 G data rate (e.g., for a loopback test), but may not be able to facilitate analysis of data incoming at a 800 G data rate (e.g., for a FEC test). That is, in some examples, the FPGA 507 may not be configured to analyze 800 G data rates coming through the second connection port assembly 502. In these instances, the second connection port assembly 502 may be required to loop the data back to the first connection port assembly 501, which may be able to facilitate the analysis (e.g., via the FPGA 507). In some examples, testing results may be displayed on a display component (e.g., display 103) of a data center testing device (as described above). A loopback path to conduct an 800 G cable test is illustrated in FIG. 5E.

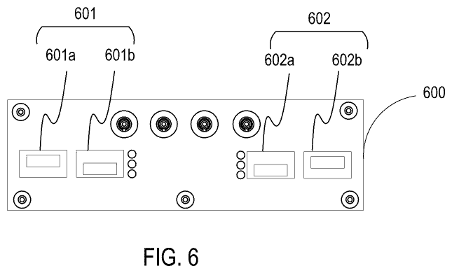

FIG. 6 illustrates a back side view of multiport testing module 600, according to an example of the present disclosure. The multiport testing module 600 includes a plurality of modular elements used for data center installation, testing, measurement, and maintenance, and may include a printed circuit board similar to the PCB 500 illustrated in FIG. 5. So, in some examples, the multiport testing module 600 may include a first connection port assembly 601 and a second connection port assembly 602. The first connection port assembly 601 may include a first QSFP-DD800 port 601a and a first OSFP-800 port 601b. The second connection port assembly 602 may include a second QSFP-DD800 port 602a and a second OSFP-800 port 602b.

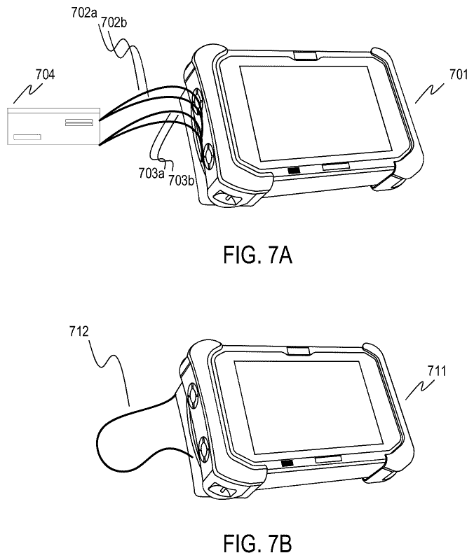

FIG. 7A illustrates a diagram of data center testing device 701 connected to workstation 704, according to an example of the present disclosure. In particular, a first pair of cables 702a, 702b may couple the data center testing device 701 to the workstation 704 via a first connection port (e.g., similar to the first connection port assembly 501), and a second pair of cables 703a, 703b may couple the data center testing device 701 to the workstation 704 via a second connection port (e.g., similar to the second connection port assembly 502). Accordingly, the data center testing device 701 may be able to test various aspects of the workstation 704, as described above.

FIG. 7B illustrates a diagram of data center testing device 711 coupled to a cable 712 to be tested, according to an example of the present disclosure. In some examples, the cable 712 may be an AOC cable utilizing a QSFP-DD800 connectors. So, in some examples, a first end of the cable 712 may be coupled to a QSFP-DD800 port of a first connection port of the data center testing device 711, and a second end of the cable 712 may be coupled to a QSFP-DD800 port of a first connection port of the data center testing device 711. Accordingly, the data center testing device 711 may be able to test various aspects of the cable 712, as described above.

Handheld testing devices presently available on the market do not typically include multiple connection ports accommodating multiple connector types. Typically, these devices include one port of a particular connector type (e.g., either OSFP800 or QSFP-DD800, or two ports having two different connector types (e.g., OSFP800 and QSFP-DD800). As a result, testing in current practice may require a testing device to connect one end of a cable to a testing device and may require the other end of the cable to be connected to a testing system, where (typically) the testing data may be required to be sent away for analysis. It may be appreciated that this may be cumbersome and unnecessarily complicated for an on-site technician.

However, as described above, because a data center testing device as described herein may include a first connection port assembly that may accommodate multiple connector types and a second connection port assembly also accommodating multiple connector types, this may enable both ends of a cable under test to the plugged into a data center testing device as described, thereby eliminating a need for two testing devices during cable testing.

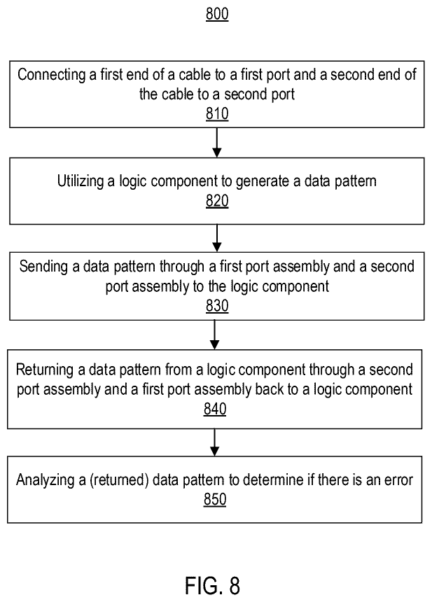

FIG. 8 illustrates a method for testing a cable for a data center, according to an example of the present disclosure. The method 800 is provided by way of example, as there may be a variety of ways to carry out the method described herein. Each block shown in FIG. 8 may further represent one or more processes, methods, or subroutines, and one or more of the blocks may include machine-readable instructions stored on a non-transitory computer-readable medium and executed by a processor or other type of processing circuit to perform one or more operations described herein. In some examples, the method 800 may be executed or otherwise performed by other systems, or a combination of systems.

Reference is now made with respect to FIG. 8. At 810, the method may include connecting a first end of a cable (e.g., an AOC cable) to a first port (e.g., port 501a) of a first port assembly (e.g., port assembly 501) of a data center testing device, and a second end of the cable to a second port (e.g., port 502a) of a second port assembly (e.g., port assembly 502) of the data center testing device.

At 820, the method may include utilizing a logic component of the data center testing device (e.g., the FPGA 507) to generate a data pattern.

At 830, the method may include sending the data pattern from the logic component through the first port assembly of the data center testing device, over the cable, through the second port assembly of the data center testing device, and back to the logic component.

At 840, the method may include returning the data pattern from the logic component, through the second port assembly of the data center testing device, over the cable, through the first port assembly of the data center testing device, to the logic component.

At 850, the method may include analyzing the (returned) data pattern (e.g., by the first logic component) to determine there is an error.

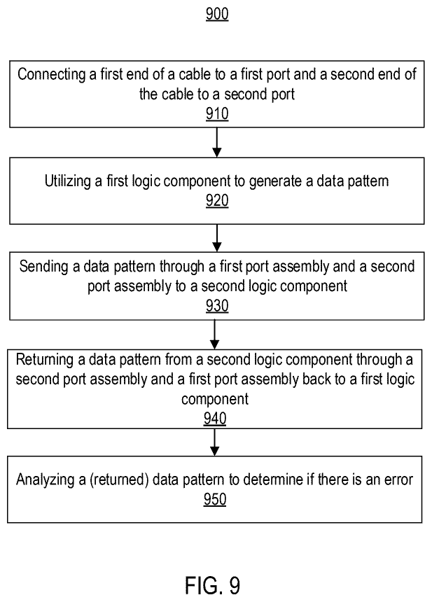

FIG. 9 illustrates a method for testing a cable for a data center, according to an example of the present disclosure. The method 900 is provided by way of example, as there may be a variety of ways to carry out the method described herein. Each block shown in FIG. 9 may further represent one or more processes, methods, or subroutines, and one or more of the blocks may include machine-readable instructions stored on a non-transitory computer-readable medium and executed by a processor or other type of processing circuit to perform one or more operations described herein. In some examples, the method 900 may be executed or otherwise performed by other systems, or a combination of systems.

Reference is now made with respect to FIG. 9. At 910, the method may include connecting a first end of a cable (e.g., an AOC cable) to a first port (e.g., port 501a) of a first port assembly (e.g., port assembly 501) of a data center testing device, and a second end of the cable to a second port (e.g., port 502a) of a second port assembly (e.g., port assembly 502) of the data center testing device.

At 920, the method may include utilizing a logic component of the data center testing device (e.g., the MUX 504) to generate a data pattern.

At 930, the method may include sending the data pattern from the logic component through the first port assembly of the data center testing device, over the cable, through the second port assembly of the data center testing device, and to a second logic component (e.g., MUX 506).

At 940, the method may include returning the data pattern from the second logic component, through the second port assembly of the data center testing device, over the cable, through the first port assembly of the data center testing device, back to the first logic component.

At 950, the method may include analyzing the (returned) data pattern (e.g., by the first logic component) to determine there is an error.

Examples described herein may provide testing device for testing conditions associated with a data center, comprising a processor, a memory to store machine readable instructions executable by the processor to perform data center testing, an input/output (I/O) device comprising a display, a first connector port assembly comprising a first port and a second port, and a second connector port assembly comprising a third port and a fourth port, and a logic component to generate a data pattern, send the data pattern through the first port on the testing device, receive the data pattern, and return the data pattern through the second port to the first port to analyze the returned data pattern to determine an error. In some examples, a connector type of the first port and the third port are same, and the connector type of the first port and the third port is an OSFP800 connector type. In some examples, a connector type of the second port and the fourth port are same, and the connector type of the second port and the fourth port is a QSFP-DD800 connector type. In some examples, the logic component is a field programmable gate array (FPGA), and the first connector port assembly, the second connector port assembly, and the logic component are included in a pluggable module for the testing device.

Examples described herein may also provide a method for testing conditions associated with a data center, the method comprising receiving a first end of a cable at a first port on a testing device, the first port having a first connector type, receiving a second end of the cable at a second port on the testing device, generating a data pattern via a logic component of the testing device, sending the data pattern through the first port on the testing device and over the cable to the second port on the testing device, receiving the data pattern at the logic component of the testing device, returning the data pattern through the second port on the testing device and over the cable to the first port on the testing device, and analyzing the returned data pattern to determine an error. In the examples provided herein, the second port on the testing device has the first connector type, the first connector type is an OSFP800 connector type, the first connector type is a QSFP-DD800 connector type, and the second port on the testing device has a second connector type, and the logic component is an FPGA.

Examples described herein may further provide a modular data center testing device comprising a processor to determine test results for a plurality of tests performed by the modular data center testing device, a backplane carrying power and communication signals, a plurality of interfaces connecting a base module to a plurality of modules removably connected to the base module, a testing module comprising a first connector port assembly comprising a first port and a second port; and a second connector port assembly comprising a third port and a fourth port; and a memory storing computer-executable instructions, which when executed by the processor, cause the processor to generate a data pattern via a first logic component, send the data pattern through the first connector port assembly to the second connector port assembly, receive the data pattern at a second logic component, return the data pattern through the second connector port assembly to the first connector port assembly, and analyze the returned data pattern at the first logic component to determine an error. In some examples, a connector type of the first port and the third port are the same, the connector type is OSFP800, the connector type is QSFP-DD800, the first port and the second port have different connector types, and the first logic component and second logic component are MUX units.

What has been described and illustrated herein are examples of the disclosure along with some variations. The terms, descriptions, and figures used herein are set forth by way of illustration only and are not meant as limitations. Many variations are possible within the scope of the disclosure, which is intended to be defined by the following claims-and their equivalents-in which all terms are meant in their broadest reasonable sense unless otherwise indicated.

What is claimed is:

1. A testing device for testing conditions associated with a data center, comprising:
a processor;
a memory to store machine readable instructions executable by the processor to perform data center testing;
an input/output (I/O) device comprising a display;
a first connector port assembly comprising a first port and a second port; and
a second connector port assembly comprising a third port and a fourth port; and
a logic component to generate a data pattern, send the data pattern through the first port on the testing device, receive the data pattern, and return the data pattern through the second port to the first port to analyze the data pattern to determine an error.

2. The testing device according to claim 1, wherein a connector type of the first port and the third port are same.

3. The testing device according to claim 2, wherein the connector type of the first port and the third port is an Octal Small Form Factor Pluggable 800-gigabyte (OSFP800) connector type.

4. The testing device according to claim 1, wherein a connector type of the second port and the fourth port are same.

5. The testing device according to claim 3, wherein the connector type of the second port and the fourth port is a Octal Small Form Factor Pluggable 800-gigabyte (QSFP-DD800) connector type.

6. The testing device according to claim 1, wherein the logic component is a multiplexer unit (MUX).

7. The testing device according to claim 6, wherein the logic component is an field programmable gate array (FPGA).

8. The testing device according to claim 6, wherein the first connector port assembly, the second connector port assembly, and the logic component are included in a pluggable module for the testing device.

9. A method for testing conditions associated with a data center, the method comprising:
receiving a first end of a cable at a first port on a testing device, the first port having a first connector type;
receiving a second end of the cable at a second port on the testing device;
generating a data pattern via a first logic component of the testing device;
sending the data pattern through the first port on the testing device and over the cable to the second port on the testing device;
receiving the data pattern at a second logic component of the testing device;
returning the data pattern through the second port on the testing device and over the cable to the first port on the testing device; and
analyzing the data pattern to determine an error.

10. The method of claim 9, wherein the second port on the testing device has the first connector type.

11. The method of claim 9, wherein the first connector type is an OSFP800 connector type.

12. The method of claim 9, wherein the first connector type is a QSFP-DD800 connector type.

13. The method of claim 9, wherein the second port on the testing device has a second connector type.

14. The method of claim 9, wherein the first logic component is an FPGA and the second logic component is a MUX unit.

15. A modular data center testing device comprising:
a processor to determine test results for a plurality of tests performed by the modular data center testing device;
a backplane carrying power and communication signals;
a plurality of interfaces connecting a base module to a plurality of modules connected to the base module;
a testing module comprising:
a first connector port assembly comprising a first port and a second port; and
a second connector port assembly comprising a third port and a fourth port; and
a memory storing computer-executable instructions, which when executed by the processor, cause the processor to:
generate a data pattern via a first logic component;
send the data pattern through the first connector port assembly to the second connector port assembly;
receive the data pattern at a second logic component;
return the data pattern through the second connector port assembly to the first connector port assembly; and
analyze the data pattern at the first logic component to determine an error.

16. The modular data center testing device of claim 15, wherein a connector type of the first port and the third port are same.

17. The modular data center testing device of claim 16, wherein the connector type is OSFP800.

18. The modular data center testing device of claim 16, wherein the connector type is QSFP-DD800.

19. The modular data center testing device of claim 15, wherein the first port and the second port have different connector types.

20. The modular data center testing device of claim 15, wherein the first logic component and the second logic component are MUX units.
